(19) United States
(12) Patent Application Publication
(10) Pub. No.: US 2019/0277573 A1
(43) Pub. Date: Sep. 12, 2019

(54) HEAT DISSIPATING ASSEMBLY

(71) Applicant: GE Aviation Systems LLC, Grand Rapids, MI (US)

(72) Inventors: Michel Engelhardt, Woodbury, NY (US); Judd Everett Swanson, Cooper City, FL (US)

(21) Appl. No.: 16/416,343

(22) Filed: May 20, 2019

Related U.S. Application Data
(63) Continuation of application No. 14/460,655, filed on Aug. 15, 2014.

(51) Int. Cl. F28D 15/02; H01L 23/427; F28D 15/04

(52) U.S. Cl. CPC F28D 15/0275; H01L 23/427; F28F 2215/06; F28D 15/04; F28F 2275/20; F28D 15/046

(57) ABSTRACT

A heat dissipating assembly includes a substrate configured to support at least one heat producing component and a thermally conductive cooling fin extending from the substrate, wherein heat is conducted away from the heat producing component.

### CROSS REFERENCE TO RELATED APPLICATION(S)

This application claims priority to and benefit of U.S. patent application Ser. No. 14/460,655 filed Aug. 15, 2014, which is incorporated herein in its entirety.

### BACKGROUND OF THE INVENTION

Heat producing devices, such as printed circuit boards, often contain heat producing components, such as processors or voltage regulators, which generate heat in sufficient amounts that may impact the performance of the device, unless the heat is removed. A thermal plane may be provided in combination with the heat producing devices to form an assembly to aid in the removal of heat, typically by providing additional conductive pathways to disperse the heat.

### BRIEF DESCRIPTION OF THE INVENTION

In one aspect, a heat dissipating assembly includes a first thermally conductive substrate defining at least one cooling fin extending away from the first substrate and defining at least one cavity having a corresponding at least one opening, at least one heat pipe, each one heat pipe received within a corresponding one cavity, and conductively coupled with the first substrate, and a second thermally conductive substrate enclosing the at least one opening to fix the at least one heat pipe within the at least one cavity.

### BRIEF DESCRIPTION OF THE DRAWINGS

In the drawings:

FIG. 1 is a schematic cross-sectional view of a heat producing device in the form of a printed circuit board assembly in conductive contact with the heat dissipating assembly according to one embodiment of the invention.

FIG. 2 is an exploded cross-sectional view of the heat dissipating assembly according to one embodiment of the invention.

FIG. 3 is a top-down view of a heat pipe, taken along line 3-3 of FIG. 2, according to one embodiment of the invention.

FIG. 4 is a cross-sectional view of the heat pipe illustrating the operation of the heat transfer.

FIG. 5 is a perspective view of the heat dissipating assembly and piezo cooler device, according to a second embodiment of the invention.

FIG. 6 is a top-down view of the heat pipe, taken along line VI-VI of FIG. 5, according to a second embodiment of the invention.

### DESCRIPTION OF EMBODIMENTS OF THE INVENTION

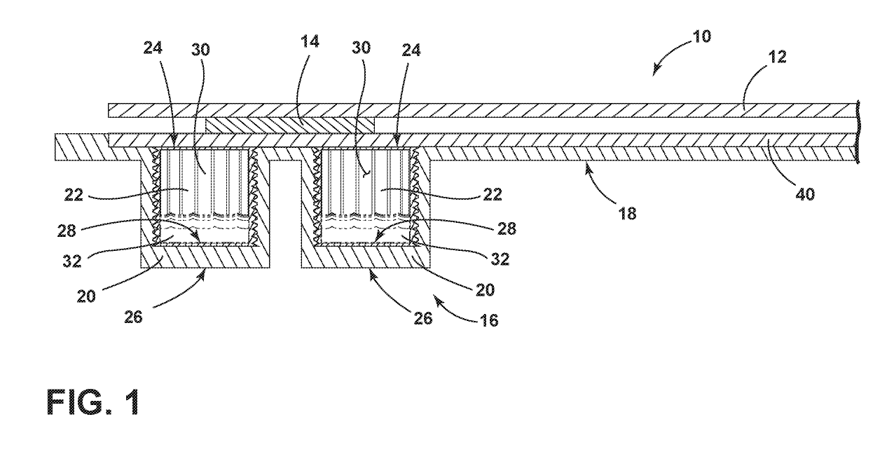

The embodiments of the present invention are related to a heat dissipating assembly configured to provide cooling to a heat producing component. In the embodiment of FIG. 1, a printed circuit board (PCB) assembly 10 is shown comprising a PCB 12 having at least one heat producing component 14, such as a microprocessor, or silicon carbine metal-oxide semiconductor field effect transistor (MOSFET).

The PCB assembly 10 is shown proximate to a heat dissipating assembly 16 having a thermally conductive substrate 18, at least one thermally conductive cooling fin 20, and a thermally conductive heat pipe 22. Each of the substrate 18, cooling fin 20, and heat pipe 22 may be machined or manufactured from a same or dissimilar material having a high thermal conductivity. Non-limiting examples of materials having a high thermal conductivity may include aluminum, copper, or various alloys. For purposes of the invention, the type of material is not limiting. All things being equal, the higher the thermal conductivity the better. Lesser thermal conductive will merely reduce the heat transfer performance.

At least a portion of the substrate 18 may be in thermally conductive relationship with the heat producing component 14 such that heat generated by the heat producing component 14 may be conducted to the substrate 18. For example, as shown, the substrate 18 may support and/or abut the heat producing component 14. Additionally, embodiments of the invention may include, for example, a layer of thermally conductive material, such as a thermal epoxy, between the substrate 18 and the heat producing component 14, to provide for increased thermal conductivity between the heat producing component 14 and the heat dissipating assembly 16.

The cooling fins 20 are thermally coupled with, and extend away from, the substrate 18, opposite the PCB assembly 10. The cooling fin 20 may be configured to provide for removing heat, for example, by convection, when exposed to a fluid, such as air, gas coolant, or liquid coolant. Example configurations for removing heat by convection may include designing the cooling fin 20 having a geometric cross-sectional shape, such as a square, circle, triangle, ellipse, etc., to increase surface area for convection to take place. Additional embodiments of the invention may further include, for example, a patterned outer surface. As shown, embodiments of the invention may include a plurality of cooling fins 20, which may be arranged in an arrayed-type pattern, and positioned proximate to the heat producing component 14.

Each cooling fin 20 may further include a conductively coupled heat pipe 22, configured in an elongated shape, such as a cylinder, located within the fin 20, and extending along at least a portion of the fin 20. In this sense, the elongated heat pipe 22 includes a first end 24 proximate to, and conductively coupled, including direct and indirect abutment, to, the substrate 18 and an opposing second end 26 being distal from the substrate 18, along the extended portion of the fin 20. The heat pipe 22 may further include an inner surface 28 defining a fluid reservoir 30 containing a phase change fluid 32, which may, for example, change phases from a liquid to a gas.

The phase change fluid 32 may be selected or configured to provide for a particular heat of vaporization, or enthalpy of vaporization, which is the combined internal energy and enthalpy change required to transform a given quality of a fluid from a liquid into a gas, at a given pressure. In this sense, the heat of vaporization of the phase change fluid 32 defines the amount of heat absorbed by the fluid 32 to change the phase of the fluid 32 from a liquid to a gas, and conversely, how much heat is released from the fluid 32 when the gas condenses back to a liquid. Furthermore, embodiments of the invention may include a sealed heat pipe 22 configuration such that the pressure within the fluid reservoir 30 may be modified to provide a selected heat of vaporization. The particular phase change fluid 32 may be selected based on the expected temperatures to be encountered during the operation of the heat dissipating assembly to ensure the phase change will occur. Non-limiting examples of phase change fluids 32 that may be utilized include water, ammonia, methanol, acetone, Freon, or any combination thereof. Phase change fluids 32 may further be selected based on their compatibilities or incompatibilities with the heat pipe 22 materials or construction.

While the illustrated example shows the phase change fluid 32 pooled near the second end 28 of the heat pipe 22, embodiments of the invention may include a heat pipe 22 configuration with a relatively small cross-sectional area or diameter, such that circulation of the fluid 32 occurs without the assistance of, and sometimes in opposition to, external forces such as gravity. This type of circulation is known as capillary action, and may provide for a heat pipe 22 configuration where gravitational effects on the phase change fluid 32 is negligible. Stated another way, embodiments of the invention may include a heat pipe 22 configuration wherein the phase change fluid 32 is dispersed over the entire fluid reservoir 30, as opposed to pooled at one end 24, 28 of the reservoir 30. Another effect of the above-described capillary action embodiment may include a heat pipe 22 configuration where, due to the dispersing of the phase change fluid 32, may be configured in any orientation.

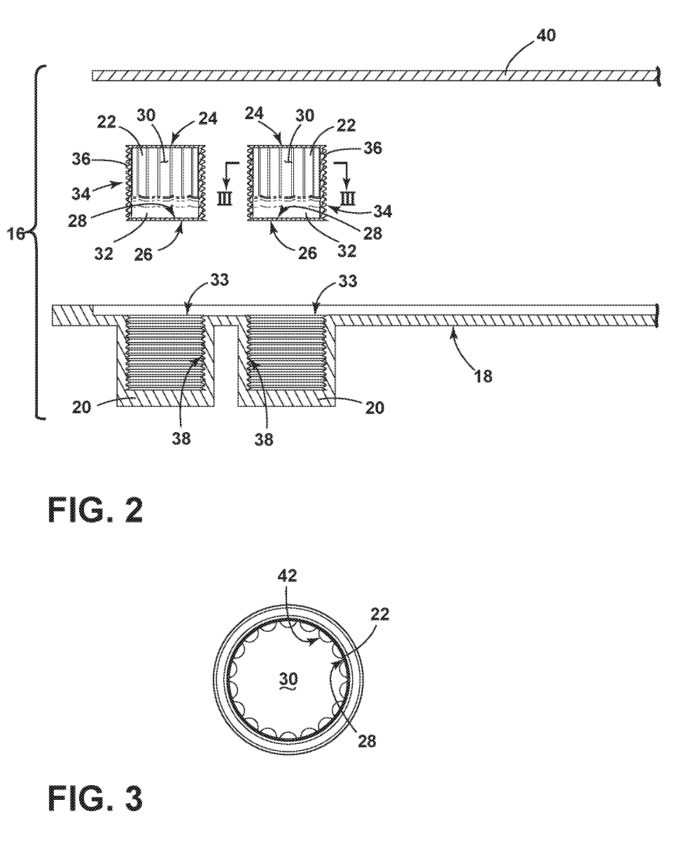

FIG. 2 illustrates an exploded cross-sectional view of the heat dissipating assembly 16 of FIG. 1. As shown, the heat pipe 22 may be independently constructed and/or configured, and assembled into the cooling fin 20, for example, through an opening 33 of the substrate 18, cooling fin 20, and/or heat dissipating assembly 16, at a later time. In this example, at least a portion of the heat pipe 22 may include, for example, a mechanical fastener configuration, illustrated as the heat pipe 22 including a screw 34 having a threaded exterior surface 36. The cooling fin 20 may correspondingly be configured to receive the mechanical fastener, such as a threaded inner surface 38, as shown. In this configuration, the heat pipe screw 34 may be fixedly or removably received within the cooling fin 20, through the opening 33, during assembly.

Embodiments of the heat dissipating assembly 16 may further include a second substrate portion 40 which may fixedly or removably provide or restrict access to the heat pipe 22 and/or the opening 33. The second substrate portion 40 may comprise the same as, or a different material than, the substrate 18. For example, in a configuration where the second substrate portion 40 may directly abut the heat producing component 14, it may be desirable to configure the second substrate portion 40 as a different material that better matches the coefficient of thermal expansion of the heat producing component 14 to ensure a reliable thermal contact between the component 14 and substrate 18 occurs.

FIG. 3 illustrates a cross section of the inner surface 28 of the heat pipe 22, according to one embodiment of the invention. In this example, the inner surface 28 may comprise a patterned sidewall 42, shown as semi-circular ridges radially arranged about the surface 28 that may be sized to provide for the capillary action of the phase change fluid 32. As explained above, the interaction of the phase change fluid 32 with the patterned sidewall 42 creates a capillary action which draws and stores the fluid 32 along the elongated shape of the heat pipe 22, ensuring a reliable thermal conductivity between the fluid 32 and the heat pipe 22.

Embodiments of the heat pipe 22 may include, for example, machining the patterned sidewall 42 into the inner surface 28, or forming the sidewall 42 during casing of the pipe 22. Additional manufacturing or assembly embodiments of the heat pipe 22 may be included. While the heat pipe 22 is illustrated having a circular cross section, embodiments of the invention may include alternative cross-sectional pipe 22 shapes, such as a square, triangle, ellipse, etc. Furthermore, additional patterned sidewalls 42 may be included in embodiments of the invention. The pattern of the sidewalls 42 may be configured based on the phase change fluid 32 to provide for optimized capillary action, as explained above.

Alternatively, embodiments of the invention may include, for example, a screw casing, wherein the heat pipe 22 may be fixed, such as by adhesive, into the screw casing, which may then be received by the threaded inner surface 38 of the cooling fin 20. In another alternative embodiment of the invention, the heat pipe 22 may be integrated or machined directly into the cooling fin 20. In yet another alternative embodiment of the invention, at least one of the threaded exterior surface 36 of the heat pipe 22 or threaded inner surface 38 of the cooling fin 20 may include a thermally conductive later, such as tape, a coating, or an epoxy, to provide for increased thermal conductivity or a more reliable thermal contact.

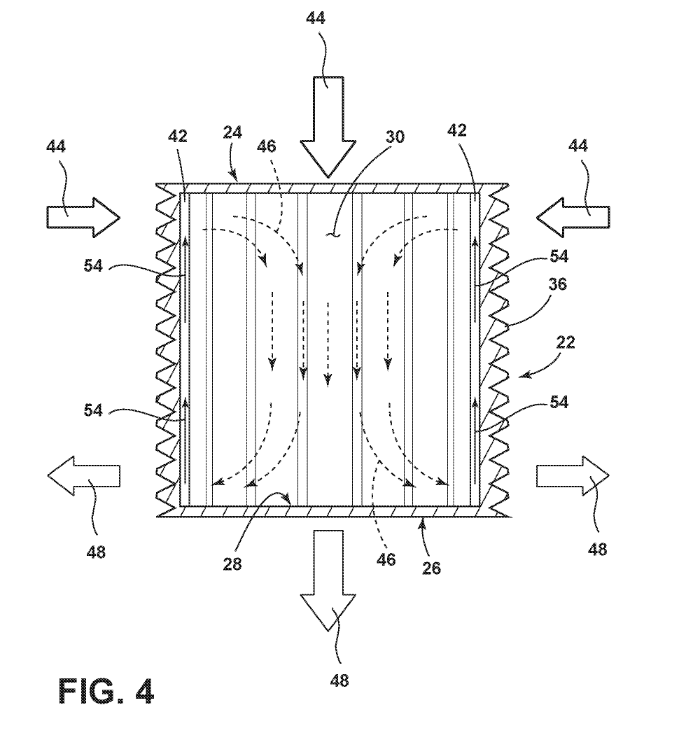

FIGS. 2, 3, and 4 illustrate the heat transfer cycle of the heat pipe 22 and phase change fluid 32. The substrate 18, cooling fin 20, and heat pipe 22 are each configured in a thermally conductive relationship with each other such that a heat conduction path may exist, tri-directionally, between the components 18, 20, 22. Thus, in one exemplary scenario, heat generated by the heat producing component 14 is conductively transferred to the substrate 18, which may be further conductively transferred to the heat pipe 22 (In FIG. 4, illustrated as arrows 44), for example, via the first end 24 of the pipe 22, and/or via the substrate 18 to the cooling fin 22, and from the cooling fin 20 to the pipe 22. The heat conducted to the heat pipe 22 may then be conductively transferred to, or absorbed into, the phase change fluid 32, which, in response to the heat conducted from the substrate 18 and/or cooling fin 22, changes phases from a liquid to a gas (illustrated as dotted line 46), absorbing at least a portion of the heat.

In FIG. 4, the phase change fluid gas 46, may traverse along at least a portion of the heat pipe 22 and condense (i.e. change phase back to a liquid) along the inner sidewalls 42 of the heat pipe 22, releasing the stored portion of the heat (illustrated as arrows 48) into a wall 42 of the heat pipe 22, or to the cooling fin 20. The heat may then, for example, be released to the local ambient air surrounding the cooling fin 20. In this example, a portion of the elongated heat pipe 22 spaced from the substrate 18 and heat producing component 14, and/or the extension of the cooling fin 20 corresponding to, and in a thermal relationship with, the pipe 22, may be cooler, or at a lower temperature, than another portion of the pipe 22 and fin 20 proximate to the substrate 18 and component 14. The phase change fluid liquid, in turn, disperses back toward the heat producing component 14, along the patterned sidewalls 42 of the inner surface 28, by capillary action (illustrated by arrow 54), ready to absorb (?) heat.

In this sense, the substrate 18, heat pipe 22, and cooling fin 20 are configured such that heat generated by the heat producing component 14 is absorbed by at least the heat pipe 22, and consequently, the phase change fluid 32 when vaporizing, and is carried away, or removed from the heat producing component 14 and/or substrate 18 by the phase change fluid 32 gas, to another portion of the heat pipe 22, spaced away from the heat producing component 14. At the another, cooler, portion of the heat pipe 22, the phase change fluid 32 gas condenses along the patterned sidewall 42 along the inner surface 28 of the pipe 22, releasing the heat back into the pipe 22 and consequently, the cooling fin 20 relative to the another portion of the pipe 22. The cooling fin 20 may then further dissipate the heat to the local environment, via convection, as explained above.

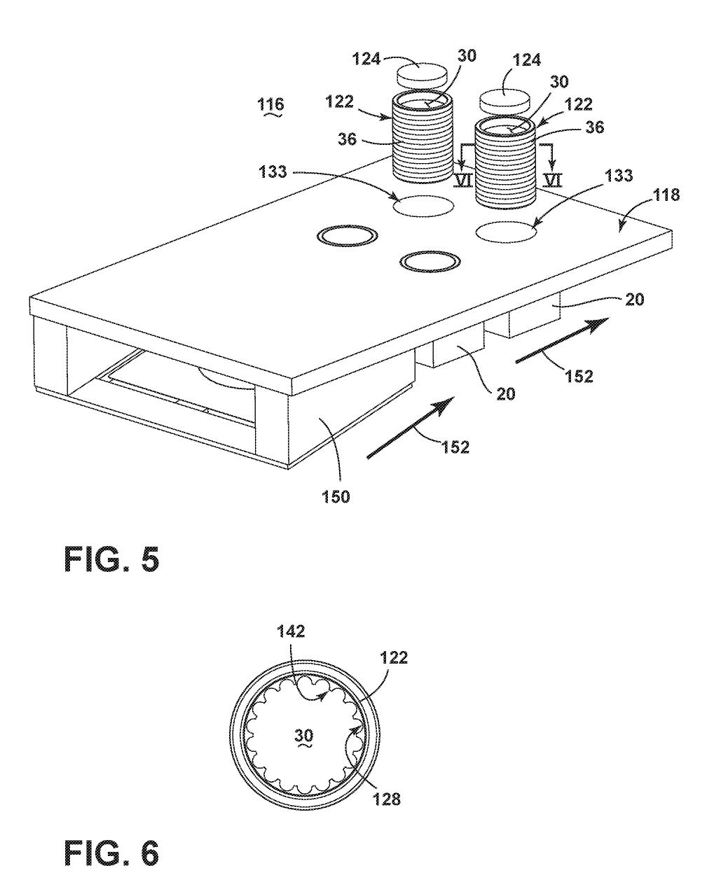

FIG. 5 illustrates an alternative heat dissipating assembly 116 according to a second embodiment of the invention. The second embodiment is similar to the first embodiment; therefore, like parts will be identified with like numerals increased by 100, with it being understood that the description of the like parts of the first embodiment applies to the second embodiment, unless otherwise noted. A difference between the first embodiment and the second embodiment is that heat pipe 122 of the second embodiment may be configured having a fixed or removable first end 124, and may be received directly into the opening 133 of the substrate 118 such that the first end 124 may abut a heat producing component 14 (not shown) directly.

Another difference between the first embodiment and the second embodiment is that heat dissipating assembly 116 of the second embodiment may further include a component configured to generate a fluid movement across the cooling fins 20 to provide increased convection cooling of the fins 20. In the illustrated example, a piezo cooler 150 may produce a jet of air (shown as arrows 152) across the cooling fins 20.

FIG. 6 illustrates a cross section of the inner surface 128 of the heat pipe 122, according to the second embodiment of the invention. In this example, the inner surface 128 may comprise an alternatively patterned sidewall 142, shown having inverse semi-circular ridges, compared to the patterned sidewall 42 of the first embodiment, radially arranged about the surface 128.

Many other possible embodiments and configurations in addition to that shown in the above figures are contemplated by the present disclosure. For example, while the above-described examples of heat producing components 14 may primarily described as types of electrical components (e.g. resistors, inductors, capacitors, power regulators, pulse laser control boards, etc.), embodiments of the invention may be applicable to alternative heat dissipating or cooling configurations, for example, in dissipating heat from coolant or oil in a generator, or in dissipating heat from a line replaceable unit, for example, in an aircraft. Furthermore, while only a single heat producing component 14 is illustrated, embodiments of the invention may include pluralities of heat pipes 22 and cooling fins 20 to account for additional heat producing components 14 associated with a single heat dissipation assembly 16. The pluralities of heat pipes 22 and cooling fins 20 may be grouped proximate to the respective heat producing components 14, or distributed across at least a portion of the substrate 18.

Furthermore, the configuration of the heat dissipating assembly 16, including, for example, cooling fin 20 size, length, and height, or heat pipe 22 length and phase change fluid 32 composition, may be selected based on the heat dissipation needs of a particular application, or to ensure a desired cooling temperature. For instance, a high heat flux, or transient duration heat producing component 14 may have different heat dissipating needs than a heat producing component 14 that generates a steady state heat flux, and thus may need additional heat dissipating means. Likewise, a heat producing component 14 of a line-replaceable unit on an aircraft may have size or height restrictions for cooling fins 20. In yet another example, a heat dissipating assembly 16 exposed to liquid coolant may be configured with a smaller, or shorter heat pipe 22 and/or cooling fins 20, due to improved heat dissipation from the fins 20 to the liquid coolant.

In yet another embodiment of the heat dissipating assembly 16, more than one heat pipe 22 may be coupled with a single cooling fin 20, for example, in a stacked configuration along the extending direction of the fin 20, to provide for increased heat dissipation. In even yet another embodiment of the heat dissipating assembly 16, the cooling fins 20 may further comprise a coating, such as a lusterless black coating including a mixture of carbon black particles, configured to remove and/or dissipate additional heat from at least one of the heat pipe 22 or substrate 18 by radiation. Additionally, the design and placement of the various components may be rearranged such that a number of different configurations could be realized.

The embodiments disclosed herein provide a heat dissipating assembly having a heat pipe. One advantage that may be realized in the above embodiments is that the above described embodiments have superior weight and size advantages over the conventional type heat dissipating assemblies having air cooling fins, or assemblies including, for instance, fans or liquid cooling components, to provide for cooling capabilities. Furthermore, the heat pipe provides for reduced weight, compared with a solid pin fin assembly, and provides for approximately eight times greater thermal conductivity. The thermal management system of coupling radiation, convection, and conduction provides for a heat dissipation assembly that competes with actively-cooled heat management systems (e.g. with fans, pumped coolant, etc.)

With the proposed heat dissipation assembly, a high heat dissipation can be achieved during transient or steady state heat conditions without additional heat dissipation elements, thus increasing the reliability of such heat dissipation assemblies by reducing the need for additional componentry. In addition to increased reliability, reducing components directly relates to reducing weight and volume of the assembly, and is especially beneficial in space and weight-limiting applications, such as airborne platforms. Moreover, higher heat producing component reliability can be achieved even when components do not have high heat conditions.

When designing heat dissipation assemblies, important factors to address are power, size, weight, and reliability. The above described heat dissipation assemblies have a decreased number of parts compared to a heat dissipating assembly having active air or liquid cooling, making the complete system inherently more reliable. This results in a lower electrical power, lower weight, smaller sized, increased performance, and increased reliability system. The lower number of parts and reduced maintenance will lead to a lower product costs and lower operating costs. Reduced weight and size correlate to competitive advantages.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A heat dissipating assembly, comprising:
A first thermally conductive substrate defining at least one cooling fin extending away from the first substrate and defining at least one cavity having a corresponding at least one opening;
At least one heat pipe, each one heat pipe received within a corresponding one cavity, and conductively coupled with the first substrate
A second thermally conductive substrate enclosing the at least one opening to fix the at least one heat pipe within the at least one cavity.

2. The heat dissipating assembly of claim 1 wherein the at least one cooling fin extends normally away from the first substrate.

3. The heat dissipating assembly of claim 1 wherein the at least one cooling fin is in the form of a cylinder.

4. The heat dissipating assembly of claim 3 where in the at least one heat pipe is in the form of a cylinder and the cavity is in the form of a cylinder.

5. The heat dissipating assembly of claim 1 wherein the at least one heat pipe is further fixed relative to the first substrate by way of a mechanical fastener.

6. The heat dissipating assembly of claim 1 wherein an inner surface of the at least one cavity defines a threaded inner surface and wherein an outer surface of the at least one heat pipe defines a threaded outer surface.

7. The heat dissipating assembly of claim 6 wherein the at least one heat pipe is in the form of a screw.

8. The heat dissipating assembly of claim 1 wherein the first substrate includes a generally planar surface from which the at least one cooling fin extends away from.

9. The heat dissipating assembly of claim 8 wherein the second substrate includes a generally planar surface that is shaped to be received by the generally planar surface of the first substrate.

10. The heat dissipating assembly of claim 9 wherein the first substrate includes a substrate seat sized to receive the generally planar surface of the second substrate.

11. The heat dissipating assembly of claim 1 wherein the first substrate and the second substrate have different coefficients of thermal expansion.

12. The heat dissipating assembly of claim 1, further comprising a piezo cooler connected with the first substrate and configured to direct air across an external surface of the at least one cooling fins.

13. The heat dissipating assembly of claim 1, further comprising a heat producing component in conductive contact with the second substrate.

14. The heat dissipating assembly of claim 13 wherein the second substrate comprises an alloy configured to match the coefficient of thermal expansion of the heat producing component.

15. The heat dissipating assembly of claim 13 wherein heat generated by the heat producing component is thermally transferred through the second substrate, to the at least one heat pipe, to the at least one cooling fin, and away from the second substrate via convection.

16. The heat dissipating assembly of claim 1 wherein the at least one heat pipe includes an elongated shape and further comprises a cross section configured to negate gravitational effects on the phase change fluid so that the at least one heat pipe operates in any orientation.

17. The heat dissipating assembly of claim 1 wherein the at least one heat pipe includes a patterned sidewall having semi-circular ridges radially arranged about the inner surface.

18. The heat dissipating assembly of claim 1 wherein the at least one heat pipe includes a patterned sidewall having inverse semi-circular ridges radially arranged about the inner surface.

19. The heat dissipating assembly of claim 1 wherein the at least one heat pipe includes a patterned sidewall having ridges that extend longitudinally away from the first substrate.

20. The heat dissipating assembly of claim 1 wherein the at least one cooling fin includes a plurality of cooling fins arranged in an array.
